(19) United States
(12) Patent Application Publication
(10) Pub. No.: US 2021/0132511 A1
(43) Pub. Date: May 6, 2021

(54) DISPLACEMENT DEVICE

(71) Applicant: GUANGDONG JIXUN PRECISION EQUIPMENT CO., LTD., Foshan (CN)

(72) Inventor: Chenyang DING, Foshan (CN)

(21) Appl. No.: 16/958,193

(22) PCT Filed: Oct. 30, 2018
(86) PCT No.: PCT/CN2018/112551

§ 371 Date: Dec. 21, 2020

(30) Foreign Application Priority Data
Dec. 29, 2017 (CN) 201711477956.0

(51) Int. Cl. G03F 7/20; H02K 41/035

(52) U.S. Cl. CPC G03F 7/70758; G03F 7/70775; H02K 41/0356

(57) ABSTRACT

A displacement device (1), including: a stator magnet array (10) including a plurality of first magnets (11) and a plurality of second magnets (12), the first magnets (11) and the second magnets (12) being arranged periodically in a first plane (X-Y plane); and a rotor (20) including at least a first X-coil array (A11) of a plurality of first X-coils (L11) and a first Y-coil array (A12) of a plurality of first Y-coils (L12). A body portion of the first X-coil array (A11) is disposed in a first conductor layer that is substantially parallel to the first plane (X-Y plane), and a body portion of the first Y-coil array (A12) is disposed in a second conductor layer that is substantially parallel to the first plane (X-Y plane), the first conductor layer and the second conductor layer are disposed at a distance from each other in a direction perpendicular to the first plane (X-Y plane). The first X-coils (L11) includes a pair of first XX conductors (C111) extending in a first direction and a pair of first XY conductors (C112) extending in a second direction substantially perpendicular to the first direction. The first direction and the second direction are both substantially parallel to the first plane (X-Y plane). At least one of the pair of the first XX conductors (C111) of the first X-coil (L11) is disposed in the second conductor layer, and the pair of the first XY conductors (C112) are both disposed in the first conductor layer.

### FIELD

The disclosure relates to the field of precision motion systems, and in particular to a displacement device.

### BACKGROUND

In recent years, in the field of lithography apparatus, a multi-degree-of-freedom displacement device called a maglev planar motor is used in a wafer stage and a reticle stage of a lithography machine, which can provide a multi-axis motion through applying an electromagnetic force directly to the wafer stage, based on the Lorentz force principle. The maglev planar motor generally includes two parts, i.e., a magnet array and a coil winding unit. Units in the magnet array are arranged in an alternating manner, which is very convenient for development, and effectively solves the technical bottleneck in the large stroke design. In addition, this displacement device can not only achieve a movement in six degrees of freedom, but also save intermediate transmission steps, which has compact structure and high rigidity. It can be driven directly without mechanical friction and backlash and, which facilitates to achieve higher acceleration performance and positioning accuracy, and to improve the efficiency of the motion stage, thereby realizing a higher positioning accuracy and motion acceleration. In addition, by the magnetic levitation technology, constraints on motion surface type are reduced, and it is free of contact wear during operation, making it suitable for a microelectronic equipment which requires large stroke, vacuum, ultra-clean and ultra-precision positioning. The disclosure can be applied to a variety of chip manufacturing equipment, such as a motion stage for loading and precise positioning of a wafer in a lithography machine, a reticle stage in a lithography machine, a wafer inspection device, a wafer cutting device, and a motion stage for loading and precise positioning of a wafer in a chip package device. The disclosure can also be applied to a precision motion stage in many devices such as an optical equipment, numerical control machine tool and biomedical manufacturing equipment.

Patent Document 1 discloses a displacement device including an array of rotor coils and a stator magnet array, whereof the rotor is movable in at least two directions (directions X and Y) with respect to the stator. However, each of the coils in Patent Document 1 includes a hollow structure, and is arranged such that the coils do not fill the hollow portions with respect to each other, which results in reducing the space ratio of the conductive materials, and thereby limiting the improvement on motor force.

Patent Document 1 U.S. Pat. No. 7,372,548

### SUMMARY

For addressing those technical problems above, the present disclosure provides a displacement device, including: a stator magnet array including a plurality of first magnets and a plurality of second magnets, the first magnets and the second magnets being arranged periodically in a first plane; and a rotor including at least a first X-coil array of a plurality of first X-coils and a first Y-coil array of a plurality of first Y-coils. A body portion of the first X-coil array is disposed in a first conductor layer that is substantially parallel to the first plane, and a body portion of the first Y-coil array is disposed in a second conductor layer that is substantially parallel to the first plane, the first conductor layer and the second conductor layer are disposed at a distance from each other in a direction perpendicular to the first plane. The first X-coils includes a pair of first XX conductors extending in a first direction and a pair of first XY conductors extending in a second direction substantially perpendicular to the first direction. The first direction and the second direction are both substantially parallel to the first plane. The first direction and the second direction are substantially perpendicular with each other. At least one of the pair of the first XX conductors of the first X-coil is disposed in the second conductor layer, and the pair of the first XY conductors are both disposed in the first conductor layer.

In the displacement device, preferably, the first Y-coils includes a pair of first YX conductors extending in the first direction and a pair of first YY conductors extending in the second direction; and at least one of the pair of the first YY conductors of the first Y-coil is disposed in the first conductor layer, and the pair of the first YX conductors are disposed in the second conductor layer.

In the displacement device, preferably, the rotor further includes a second X-coil array of a plurality of second X-coils; the second X-coils includes a pair of second XX conductors extending in the first direction and a pair of second XY conductors extending in the second direction; at least one of the pair of the second XX conductors of the second X-coil is disposed in the second conductor layer, and the pair of the second XY conductors are disposed in the first conductor layer; the rotor further includes a second Y-coil array of a plurality of second Y-coils; the second Y-coils includes a pair of second YX conductors extending in the first direction and a pair of second YY conductors extending in the second direction; at least one of the pair of the second YY conductors of the second Y-coil is disposed in the first conductor layer, and the pair of the second YX conductors are disposed in the second conductor layer.

In the displacement device, preferably, the first XX conductor disposed in the second conductor layer is provided between the first YX conductor and the second YX conductor which are closest to a negative direction of the second direction, and the second XX conductor disposed in the second conductor layer is provided between the first YX conductor and the second YX conductor which are closest to a positive direction of the second direction.

In the displacement device, preferably, the first YY conductor disposed in the first conductor layer is provided between the first XY conductor and the second XY conductor which are closest to a positive direction of the first direction, and the second YY conductor disposed in the first conductor layer is provided between the first XY conductor and the second XY conductor which are closest to a negative direction of the first direction.

In the displacement device, preferably, the first XX conductor disposed in the second conductor layer is provided at a side closer to the negative direction of the second direction than one of the first YX conductors or one of the second YX conductors which is closest to the negative direction of the second direction, and the second XX conductor disposed in the second conductor layer is provided at a side closer to the positive direction of the second direction than one of the first YX conductors or one of the second YX conductors which is closest to the positive direction of the second direction.

In the displacement device, preferably, the first YY conductor disposed in the first conductor layer is provided at a side closer to the positive direction of the first direction than one of the first XY conductors or one of the second XY conductors which is closest to the positive direction of the first direction, and the second YY conductor disposed in the first conductor layer is provided at a side closer to the negative direction of the first direction than one of the first XY conductors or one of the second XY conductors which is closest to the negative direction of the first direction.

In the displacement device, preferably, a distance dₓₓ in the first direction between a boundary of the first X-coil array in the negative direction of the first direction and a boundary of the second X-coil array in the negative direction of the first direction satisfies

dₓₓ=(⅓+2n/3)λₓ, wherein, n=0,1,2,3 . . . , and

a distance d_{yy} in the second direction between a boundary of the first Y-coil array in the positive direction of the second direction and a boundary of the second Y-coil array in the positive direction of the second direction satisfies:

d_{yy}=(⅓+2n/3)λ_{y}, wherein, n=0,1,2,3 . . . ,

wherein λₓ is a distance between two adjacent homo-polar magnets in the first direction, and λ_{y} is a distance between two adjacent homo-polar magnets in the second direction.

In the displacement device, preferably, a distance d_{xy} in the second direction between a boundary of the first X-coil array in the positive direction of the second direction and a boundary of the second X-coil array in the positive direction of the second direction satisfies:

d_{xy}=(n+⅙)λ_{y}, wherein, n=0,1,2,3 . . . , and

a distance d_{yx} in the first direction between a boundary of the first Y-coil array in the positive direction of the first direction and a boundary of the second Y-coil array in the positive direction of the first direction satisfies:

d_{yx}=(n+16)λₓ, wherein, n=0,1,2,3 . . . ,

wherein λₓ is a distance between two adjacent homo-polar magnets in the first direction, and λ_{y} is a distance between two adjacent homo-polar magnets in the second direction.

In the displacement device, preferably, a distance Cₙ between the pair of the first YX conductors, extending in the first direction, of the first Y-coil, satisfies:

Cₙ=(n+½)λ_{y}, wherein, n=0,1,2,3 . . . , and

a distance Cₙ between the pair of the first XY conductors, extending in the second direction, of the first X-coil, satisfies:

Cₙ=(n+½)λₓ, wherein, n=0,1,2,3 . . .

### BRIEF DESCRIPTION OF THE DRAWINGS

FIG. 1 is a schematic plan view showing a rotor and a stator magnet array of a displacement device according to a first embodiment of the present disclosure:

FIG. 2 is a schematic plan view showing an X-coil array and a Y-coil array of the rotor of the displacement device according to the first embodiment of the present disclosure;

FIG. 3 is a schematic plan view showing one of the Y-coils in the Y-coil array of the rotor of the displacement device according to a first embodiment of the present disclosure;

FIG. 4 is a schematic plan view showing an X-coil array and a Y-coil array of the rotor of the displacement device according to a second embodiment of the present disclosure;

FIG. 5A is a schematic plan view showing a Y-coil array of the rotor of the displacement device according to a third embodiment of the present disclosure;

FIG. 5B is a schematic plan view showing an X-coil array of the rotor of the displacement device according to a third embodiment of the present disclosure:

FIG. 5C is a schematic plan view showing a combined X-coil array and Y-coil array of the rotor of the displacement device according to a third embodiment of the present disclosure;

FIG. 6 is a schematic view showing a magnet array of the stator of the displacement device according to a first variant embodiment of the present disclosure:

FIG. 7 is a schematic view showing a stator magnet array of the displacement device according a second variant embodiment of the present disclosure;

FIG. 8 is a schematic view showing a stator magnet array of the displacement device according to a third variant embodiment of the present disclosure;

FIG. 9 is a schematic view showing a stator magnet array of the displacement device according to a fourth variant embodiment of the present disclosure.

### LIST OF REFERENCE NUMERALS

1—Displacement device;
10—stator magnet array;
11—First magnet;
12—Second magnet;
13—Third magnet;
20—Rotor;
L11—First X-coil;
A11—First X-coil array;
L12—First Y-coil;
A12—First Y-coil array;
C111—First XX conductor;
C112—First XY conductor;
C121—First YX conductor;
C122—First YY conductor;
L21—Second X-coil;
A21—Second X-coil array;
C211—Second XX conductor;
C212—Second XY conductor;
L22—Second Y-coil;
A22—Second Y-coil array;
C221—Second YX conductor; and
C222—Second YY conductor.

### DETAILED DESCRIPTION OF THE EMBODIMENTS

Objects, technical schemes and advantages of the present disclosure will be clearer from a detailed description of embodiments of the present disclosure in conjunction with the drawings. It should be understood that the embodiments are only for illustrating the disclosure, and not intended to limit the scope of the present disclosure. The described embodiments are only a part of the embodiments of the disclosure, but not all of the embodiments. All other embodiments obtained by an ordinary person skilled in the art based on the embodiments of the present disclosure without creative efforts are within the scope of the present disclosure.

In the description of the disclosure, it is to be understood that the terms “upper”, “lower”, and the like, which indicate orientations or positional relationships based on the orientations or positional relationships shown in the drawings, are merely for convenience in describing the disclosure and simplifying the description, and do not indicate or imply that the device or element referred to must have a specific orientation, be constructed and operated in a specific orientation, and thus, should not be construed as limiting the disclosure.

### Embodiment 1

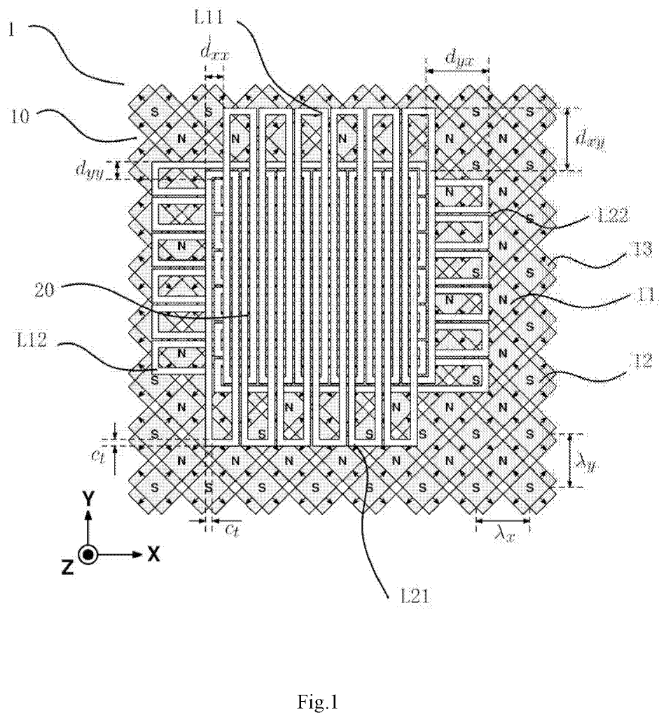

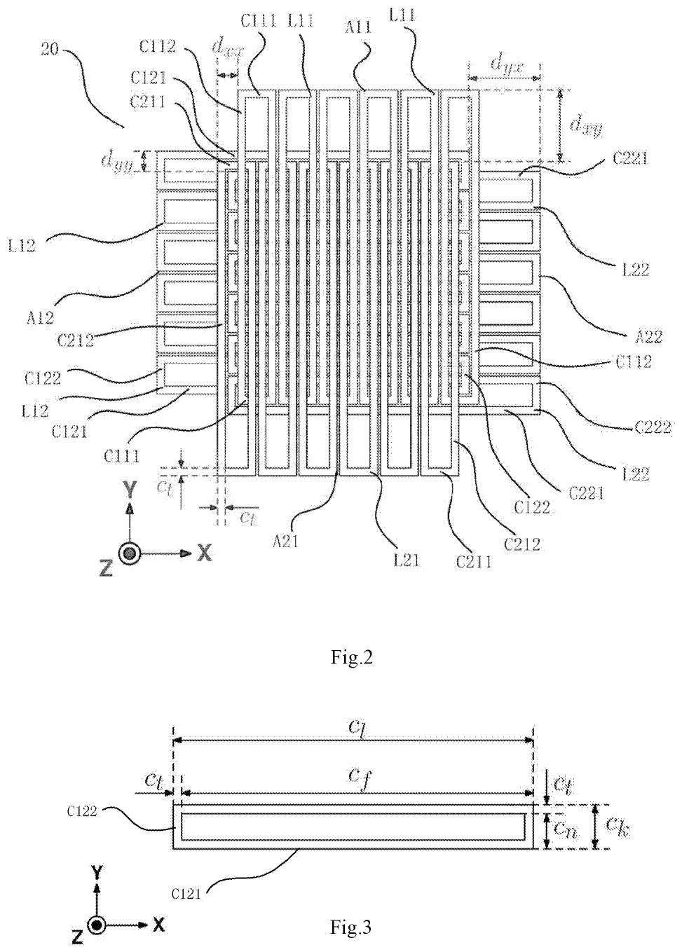

FIG. 1 is a schematic plan view showing a rotor and a stator magnet array of a displacement device according to a first embodiment of the present disclosure, and FIG. 2 is a schematic plan view showing an X-coil array and a Y-coil array of the rotor of the displacement device according to the first embodiment of the present disclosure. As shown in FIGS. 1 and 2, the displacement device according to the present disclosure includes: a stator magnet array 10 including a plurality of first magnets (N magnet) 1 and a plurality of second magnets (S magnet) 12, the first magnets 1 and the second magnets 12 are arranged in a periodical manner on a first plane (X-Y plane); and a rotor 20 including at least a first X-coil array A11 and a first Y-coil array L12, wherein the first X-coil array A11 includes a plurality of first X-coils L11 in form of rectangle and the first Y-coil array A12 includes a plurality of first Y-coils L12 in form of rectangle. A body portion of the first X-coil array A11 is disposed in a first conductor layer that is substantially parallel to the first plane, a body portion of the first Y-coil array A12 is disposed in a second conductor layer that is substantially parallel to the first plane. The “body portion” herein refers to a pair of conductors for generating motor force (Lorentz force) among the conductors constituting each coil. The pair of conductors interact with the magnet array to generate a Lorentz force of the same magnitude and direction. In embodiments of the present disclosure, specifically, it is referred to a pair of relatively long conductors among others in each coil, and detailed explanation will be described below. In addition, the first conductor layer and the second conductor are disposed at a distance from each other in a direction Z perpendicular to the first plane.

FIG. 2 is a schematic plan view showing an X-coil array and a Y-coil array of the rotor of the displacement device according to the first embodiment of the present disclosure. As shown in FIG. 2, in the rotor of the displacement device according to a first embodiment of the present disclosure, the first X-coil L11 includes a pair of first XX conductors C111 extending in a direction X (first direction) and a pair of first XY conductors C112 extending in a direction Y (second direction) substantially perpendicular to the direction X. The direction X and the direction Y are both substantially parallel to the first plane. In the first X-coil L11, at least one of the pair of the first XX conductors C111 is disposed in the second conductor layer, and the pair of the first XY conductors C112 are both disposed in the first conductor layer. That is, in the first X-coil L11, one of the first XX conductors C111 is provided in the second conductor layer, the other one is provided in the first conductor layer, and the first XY conductors C112 are both provided in the first conductor layer. Alternatively, the first XX conductors C111 are both provided in the second conductor layer, and the first XY conductors C112 are both provided in the first conductor layer. As also shown in FIG. 2, in the displacement device of the present disclosure, a first Y-coil L12 includes a pair of first YX conductors C121 extending in a direction X and a pair of first YY conductors C122 extending in a direction Y. In the first Y-coil L12, at least one of the pair of the first YY conductors C122 is disposed in the first conductor layer, and the pair of the first YX conductors C121 are disposed in the second conductor layer. That is, in the first Y-coil L12, one of the first YY conductors C122 is provided in the first conductor layer, the other one is provided in the second conductor layer, and the first YX conductors C121 are both provided in the second conductor layer. Alternatively, the first YY conductors C122 are both provided in the first conductor layer, and the first YX conductors C121 are both provided in the second conductor layer.

In addition, as shown in FIG. 2, in the displacement device of the present disclosure, the rotor 20 further includes a second X-coil array A21, which is composed of a plurality of second X-coils L21. The second X-coil L21 include a pair of second XX conductors C211 extending in a direction X and a pair of second XY conductors C212 extending in a direction Y. In the second X-coil L21, at least one of the pair of the second XX conductors C211 is disposed in the second conductor layer, and the pair of the second XY conductors C212 are both disposed in the first conductor layer. That is, in the second X-coil L21, one of the second XX conductors C211 is provided in the second conductor layer, the other one is provided in the first conductor layer, and the second XY conductors C212 are both provided in the first conductor layer. Alternatively, the second XX conductors C211 arranged oppositely are both provided in the second conductor layer, and the second XY conductors C212 arranged oppositely are both provided in the first conductor layer.

In addition, as shown in FIG. 2, in the displacement device of the present disclosure, the rotor 20 further includes a second Y-coil array A22, which is composed of a plurality of second Y-coils L22. The second Y-coil L22 includes a pair of second YX conductors C221 extending in a direction X and a pair of second YY conductors C222 extending in a direction Y. In the second Y-coil L22, at least one of the pair of the second YY conductors C222 is disposed in the first conductor layer, and the pair of the second YX conductors C221 are both disposed in the second conductor layer. That is, in the second Y-coil L22, one of the second YY conductors C222 is provided in the first conductor layer, the other one is provided in the second conductor layer, and the second YX conductors are both provided in the second conductor layer. Alternatively, the second YY conductors C222 are both provided in the first conductor layer, and the second YX conductors are both provided in the second conductor layer.

As shown in FIGS. 1 and 2, in the displacement device of the present disclosure, the stator magnet array 10 forms an operating area by extending in the X-Y plane. Each of energizing coils of the rotor 20 is disposed on another X-Y plane parallel to the magnet array to interact with the stator magnet array 10 such that the rotor can generate a displacement in at least two directions within the operating area (i.e., directions X and Y). The stator magnet array 10 includes first magnets 11 (N magnet) and second magnets 12 (S magnet). Both the N magnet and the S magnet can constitute a row of magnets and a column of magnets. The rows of N magnets and S magnets are arranged alternately; the columns of N magnets and the S magnets are also arranged alternately. In the displacement device of the present disclosure, the stator magnet array 10 may further includes third magnets 13 (H magnet) having a magnetization direction parallel to the X-Y plane, arranged in a manner called Halbuch arrangement. The magnetization direction of the third magnet 13 is indicated by arrows on the third magnet in FIG. 1, directed from the S magnet to the N magnet, to enhance a magnetic field strength at a position where the rotor above (direction +Z) the stator is located. The magnetic field strength generated by the stator magnet array 10 is periodically distributed in both the X and Y directions. A spatial period in the X direction (the distance between two adjacent homo-polar magnets) is identified as λₓ, and a spatial period in the Y direction (the distance between two adjacent homo-polar magnets) is identified as.

In the displacement device of the present disclosure, the rotor 20 includes two X-coil arrays (a first X-coil array A11 and a second X-coil array A21) and two Y-coil arrays (a first Y-coil array A12 and a second Y-coil array A22), these four coil arrays are integrally arranged in a two-layer structure including a first conductor layer and a second conductor layer. The first conductor layer and the second conductor layer extend in a respective plane parallel to the first plane (X-Y plane). That is, the two conductor layers are substantially parallel to each other and substantially parallel to the first plane in which the magnet array is located. Current of each coil array is controlled by an individual driver, separately. In the displacement device of the present disclosure, assuming that a 3-phase commutation rule is used, each group of the 3-phase coils includes three coils, and a current phase difference between the adjacent two coils are 120 degrees. Alternatively, an n-phase commutation rule (n=2, 3, 4 . . . ) can also be used, so that each group of the n-phase coils has n coils. In the displacement device of the present disclosure, a 3-phase commutation rule is adopted. As shown in FIG. 1, each coil array has two groups of 3-phase coils. Alternatively, each coil array can also have n (n=1, 2, 3 . . . ) groups of 3-phase coils. In FIG. 1, these groups of 3-phase coils are connected in series in which a current is controlled by a 3-phase driver. Alternatively, these groups of coils may not be connected in series, and a current in each group is controlled by an individual 3-phase driver.

In FIG. 1, each X-coil array is controlled by an individual driver to interact with the magnet array, whereby a force in the direction X and a force in the direction Z can be generated. Due to a positional deviation d_{xy} resulting from the difference between forces in the direction X and the direction Y generated by the two X-coil arrays, a moment in the direction Z can be generated. In addition, due to a positional deviation d_{xy} resulting from the difference between forces in the direction Z and the direction Y generated by the first X-coil array A11 and the second X-coil array A21, a moment in the direction X can be generated. Similarly, the two Y-coil arrays can also interact with the magnet array, whereby two forces in the direction Y, two forces in the direction Z, a moment in the direction Z, and a moment in the direction Y can also be generated. In summary, the four coil arrays can generate forces and moments in three directions of X, Y and Z, which allows the rotor to move with six degrees of freedom, that is, translation and rotation in three directions of X, Y and Z.

As shown in FIG. 2, in the displacement device according to the first embodiment of the present disclosure, the first XX conductor C111 disposed in the second conductor layer is provided between the first YX conductor C121 and the second YX conductor C221 which are closest to the negative direction Y (i.e., direction “−Y”), and the second XX conductor C211 disposed in the second conductor layer is provided between the first YX conductor C121 and the second YX conductor C221 which are closet to the positive direction Y. In addition, as shown in FIG. 2, the first YY conductor C122 disposed in the first conductor layer is provided between the first XY conductor C112 and the second XY conductor C212 which are closest to the positive direction X (i.e., direction “+X”), and the second YY conductor C222 disposed in the first conductor layer is provided between the first XY conductor C112 and the second XY conductor C212 which are closest to the negative direction X (i.e., direction “−X”).

Optionally, in the displacement device according to the first embodiment of the present disclosure, a distance da in the direction X between a boundary of the first X-coil array A11 in the direction −X and a boundary of the second X-coil array A12 in the direction −X may be obtained by an equation, as follows:

dₓₓ=(⅓+2n/3)λₓ, wherein, n=0,1,2,3 . . .

Optionally, a distance d_{yy} in the direction Y between a boundary of the first Y-coil array A12 in in the positive direction and a boundary of the second Y-coil array A22 in the direction +Y may be obtained by an equation, as follows:

d_{yy}=(⅓+2n/3)λ_{y}, wherein, n=0,1,2,3 . . . ,

That is, in the displacement device according to the first embodiment of the present disclosure, as shown in FIG. 1, a positional deviation in direction Y of the first Y-coil array A12 and the second Y-coil array A22 is identified herein as d_{yy}, wherein d_{yy}=(⅓+2n/3)λ_{y}, n=0, 1, 2, 3 . . . (preferably, n =0 in FIG. 1). And a positional deviation in direction X of the first X-coil array A11 and the second X-coil array A21 is identified herein as dₓₓ, wherein dₓₓ=(⅓+2n/3)λₓ, n=0, 1, 2, 3 . . . (preferably, n=0 in FIG. 1). By this arrangement, a hollow portion in a coil of the first X-coil array A11 is suitable for accommodating a conductor of the second X-coil array A21 extending in the direction Y, and a hollow portion of the first Y-coil array A12 is suitable for accommodating a conductor of the second Y-coil array A22 extending in the direction X. As a result, a space ratio of a conductor in the entire coil array is increased. Thus, the four coil arrays are arranged closely with each other, and a theoretical value of the conductor space ratio in an overlapped portion in the middle may reach approximately 100% (ignoring spaces occupied by an insulating layer between the conductors). A conductor space ratio of an edge potion is basically the same with that in a design of conventional coil array. And a conductor space ratio of the entire coil array will be significantly higher than that in a conventional design of coil array.

Optionally, in the displacement device according to the first embodiment of the present disclosure, a distance d_{xy} win the direction Y between a boundary of the first X-coil array in the direction +Y and a boundary of the second X-coil array in the direction +Y may be obtained by an equation, as follows:

d_{xy}=(n+⅙)λ_{y}, wherein, n=0,1,2,3 . . .

Optionally, a distance d_{yx} in the direction X between a boundary of the first Y-coil array A12 in the direction +X and a boundary of the second Y-coil array A22 in the direction +X may be obtained by an equation, as follows:

d_{yx}=(n+16)λₓ, wherein, n=0,1,2,3 . . .

That is, a positional deviation in direction X of the first Y-coil array A12 and the second Y-coil array A22 is identified herein as d_{yx}, wherein d_{yx}=(n+⅙)λₓ, n=0, 1, 2, 3 . . . (n=1 in FIG. 1). And a positional deviation in direction Y of the first X-coil array A11 and the second X-coil array A21 is identified herein as d_{xy}, wherein d_{xy}=((n+⅙)λ_{y}, n=0, 1, 2, 3 . . . (n=1 in FIG. 1). Thereby, the conductor space ratio of the entire coil array can be further increased.

Referring to FIGS. 1 and 2, the rotor coil array includes only a first conductor layer and a second conductor layer, the first conductor layer and the second conductor layer both include: two X-coil arrays including a first X-coil array A11 and a second X-coil array A21, and two Y-coil arrays including a first Y-coil array A12 and a second Y-coil array A22. Alternatively, the rotor may include more than two conductor layers, thereby more X-coil arrays or Y-coil arrays may be included therein.

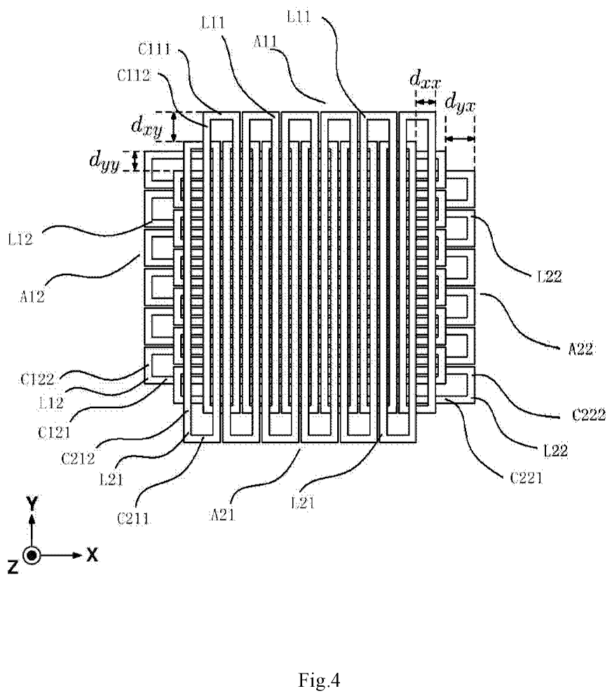

FIG. 3 is a schematic plan view showing one of the Y-coils in the Y-coil array of the rotor of the displacement device according to a first embodiment of the present disclosure. As shown in FIG. 3, the first Y coil L12 can be divided into two pairs of parallel conductors having a same width cₜ and extending linearly, one pair of which (the first YX conductor C121) extending in the direction X. and the other pair of which (the first YY conductor C122) extending in the direction Y. In order to increase a conductor space ratio, the width cₜ should be as large as possible. For a 3-phase coil, it is typically provided that cₜ≤λ_{y}/6. For an n-phase coil, it is typically provided that cₜ≤λ_{y}/(2n). Each conductor may be an integral conductor or a plurality of conductors or conductive lines substantially parallel to each other. The pair of first YX conductors C121 extending in the direction X are equal in length c and separated with a distance which is identified as cₙ. Generally, cₙ=(n+½)λ_{y}, wherein, n=0, 1, 2, 3 . . . . The pair of conductors interact with the magnet array to produce Lorentz forces of the same magnitude and direction. The pair of first YX conductors C121 can generate a motor force (Lorentz force), and thus is referred to as a “body portion” of the first Y-coil L12. The pair of first YY conductors C122 extending in the direction Y are equal in length cₙ and separated with a distance which is identified as c_{f}. Generally, c_{f}=n λₓ, wherein, n=1, 2, 3 . . . . The pair of first YY conductors C122 interacts with the stator magnet array to produce forces of the same magnitude and an opposite direction. Therefore, this pair of conductors only function as an electrical connection for the coil and is not the “body portion” of the coil. Preferably, because the group of 3-phase coils can keep the same force interacting with the magnet array in the case that an amplitude of a 3-phase current remains unchanged during movement in the X-Y plane, it is typically provided that c_{f}=nλₓ, wherein, n=1, 2, 3 . . . , which will simplify a motion control algorithm. Alternatively, it may be provided that c_{f}≥λₓ. Similarly, similar dimensional rules apply to the X-coils. Coils in this design is very suitable to be manufactured with PCB manufacturing technology.

Specifically, in the displacement device according to the first embodiment of the present disclosure, alternatively, a distance Cₙ between the first YX conductors C121, extending in the direction X, of the first Y-coil L12, may be obtained by an equation, as follows:

Cₙ=(n+½)λ_{y}, wherein, n=0,1,2,3 . . .

And, a distance Cn between the first XY conductors C112, extending in the direction Y, of the first X-coil L11, may be obtained by an equation, as follows:

Cₙ=(n+½)λₓ, wherein, n=0,1,2,3 . . .

### Embodiment 2

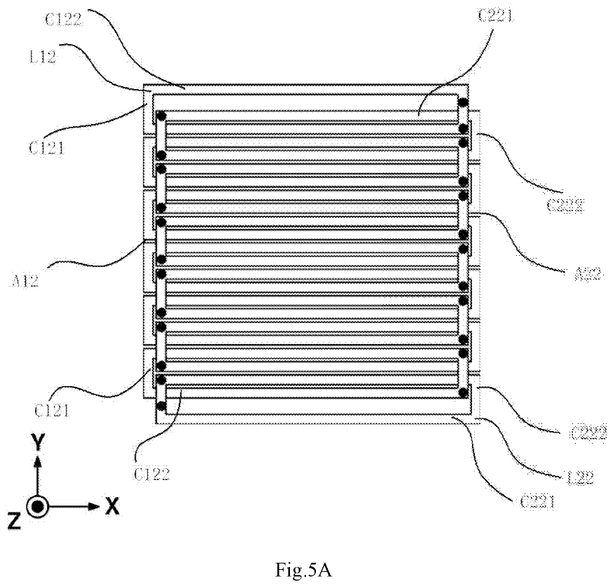

FIG. 4 is a schematic plan view showing an X-coil array and a Y-coil array of the rotor of the displacement device according to a second embodiment of the present disclosure. As shown in FIG. 4, the second embodiment is different from the first embodiment in that, the first X-coil array A11 and the second X-coil array A21 overlap to a greater extent, and the same applies to the first Y-coil array A12 and the second Y-coil array A22, thereby further reducing the planar area of the rotor 20.

Alternatively, in the displacement device according to the second embodiment of the present disclosure, as shown in FIG. 4, the first XX conductor C111 disposed in the second conductor layer is provided at a side closer to the negative direction Y (i.e., direction −Y in FIG. 4) than one of the first YX conductors C121 or one of the second YX conductors C221 which is closest to the direction −Y. And, the second XX conductor C211 disposed in the second conductor layer is provided at a side closer to the positive direction Y (i.e., direction +Y in FIG. 4) than one of the first YX conductors C121 or one of the second YX conductors C221 which is closest to the direction +Y. In addition, the first YY conductor C122 disposed in the first conductor layer is provided at a side closer to the positive direction X (i.e., direction +X in FIG. 4) than one of the first XY conductors C112 or one of the second XY conductors C212 which is closest to the direction +X. And, the second YY conductor C222 disposed in the first conductor layer is provided at a side closer to the positive direction X (i.e., direction −X in FIG. 4) than one of the first XY conductors C111 or one of the second XY conductors C212 which is closest to the direction −X.

Moreover, a positional deviation in direction X of the first Y-coil array A12 and the second Y-coil array A22 is identified herein as d_{y}x, wherein the d_{yx} satisfies: λₓ/6≤d_{yx}≤(n+½)λₓ, n=0, 1, 2, 3 . . . (n=0 in FIG. 4). And a positional deviation in direction Y of the first X-coil array A11 and the second X-coil array A21 is identified herein as d_{xy}, wherein the d_{xy} satisfies: λ_{y}/6≤d_{xy}≤(n+½)λ_{y}, n=0, 1, 2, 3 . . . (n=0 in FIG. 4). As such, the coil array designed according to the second embodiment has a smaller area in the X-Y plane than that designed according to the first embodiment.

### Embodiment 3

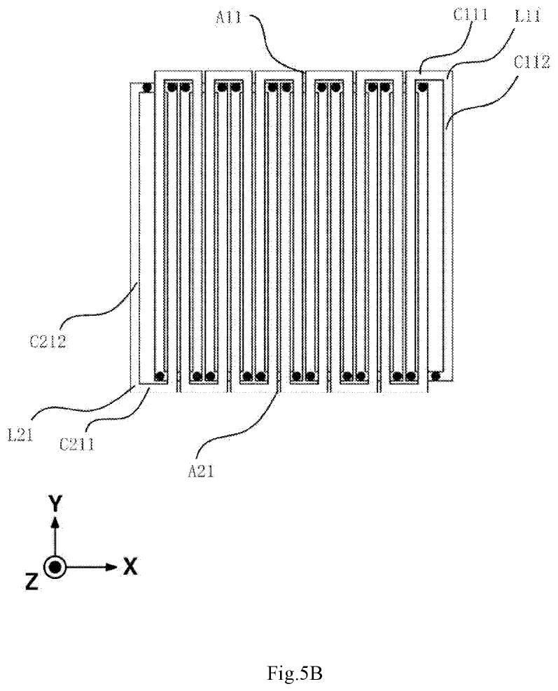

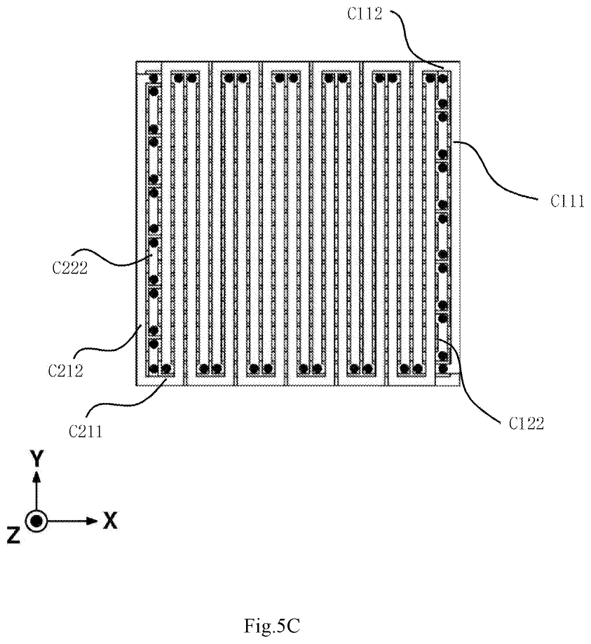

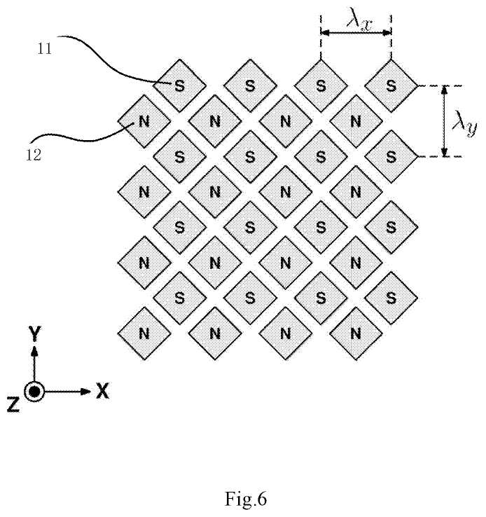

FIGS. 5A-5C are schematic plan views showing a Y-coil array of the rotor of the displacement device according to a third embodiment of the present disclosure. FIG. 5A is a schematic plan view showing a Y-coil array of the rotor of the displacement device according to a third embodiment of the present disclosure. FIG. 5B is a schematic plan view showing an X-coil array of the rotor of the displacement device according to a third embodiment of the present disclosure. FIG. 5C is a schematic plan view showing a combined X-coil array and Y-coil array of the rotor of the displacement device according to a third embodiment of the present disclosure.

As shown in FIGS. 5A-5C, the third embodiment is different from the second embodiment in that: the first X-coil array A11 and the second X-coil array A21 overlap to a greater extent, and the same applies to the first Y-coil array A12 and the second Y-coil array A22, thereby further reducing the planar area of the rotor 20. In the third embodiment of the present disclosure, a positional deviation in direction X of the first Y-coil array A12 and the second Y-coil array A22 is identified herein as d_{yx}, which satisfies: d_{yx}=(n+⅙)λₓ, let n=0, so that d_{yx}=λₓ/6. In addition, a positional deviation in direction Y of the first X-coil array A11 and the second X-coil array A21 is identified herein as d_{xy}, wherein d_{xy}=(n+⅙)λ_{y}, let n=0, so that d_{xy}=λ_{y}/6. By adopting such a design for coil array, a theoretical value of the conductor space ratio may reach approximately 100% (ignoring spaces occupied by an insulating layer between the conductors).

A first Y-coil array A12 and a second Y-coil array A22 are shown in FIG. 5A, in which black dots indicate electrical connections between conductors disposed in different conductor layers in the same coil. And, a first X-coil array A11 and a second X-coil array A21 are shown in FIG. 5B, in which black dots indicate electrical connections between conductors disposed in different conductor layers in the same coil. And, a rotor coil array formed by the first Y-coil array A12 and the second Y-coil array A22 combining with the first X-coil array A11 and the second X-coil array A21 is shown in FIG. 5C, in which black dots indicate electrical connections between conductors disposed in different conductor layers in the same coil. The values of the positional deviation d_{yx} in direction X of the two Y-coil arrays (the first Y-coil array A12 and the second Y-coil array A22) and the position deviation d_{yx} in direction Y of the two X-coil arrays (the first X-coil array A11 and the second X-coil array A21) are relatively small, which may cause torques in the directions X, Y, Z of the rotor to be too small, and increases the difficulty on control. In this case, more than one group of the coil array shown in FIG. 5C can be employed, and a certain distance is maintained in the X and Y directions, whereby larger torques (in the directions X, Y, Z) can be generated.

In the displacement device of the present disclosure, the methods for designing coils disclosed in Embodiments 1-3 can be used in combination. That is to say, in the design of a rotor, more than one group of the coil arrays shown in FIGS. 1-3 may be employed, or the coil arrays shown in FIGS. 1-3 may be combined with each other. In addition, a plurality of groups of coil arrays may be placed either side by side in the X-Y plane, or overlapped in the direction Z that is, using more conductor layers to utilize the spatial magnetic field to a greater extent, thereby generating a greater motor force.

In the above embodiments, the conductors of the same coil in different conductor layers are connected by the conductors (not shown in the Figures) that are used for connecting two conductor layers, to realize a current loop in this coil. The conductors in different conductor layers can be electrically connected via through-holes in the printed circuit board.

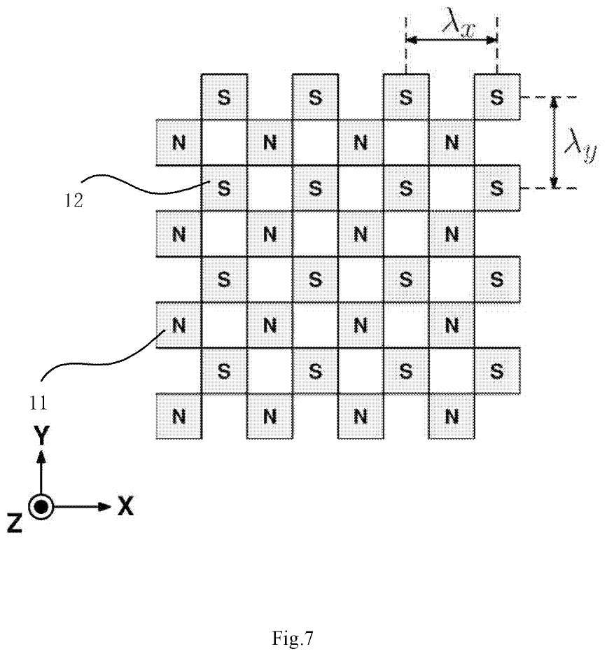

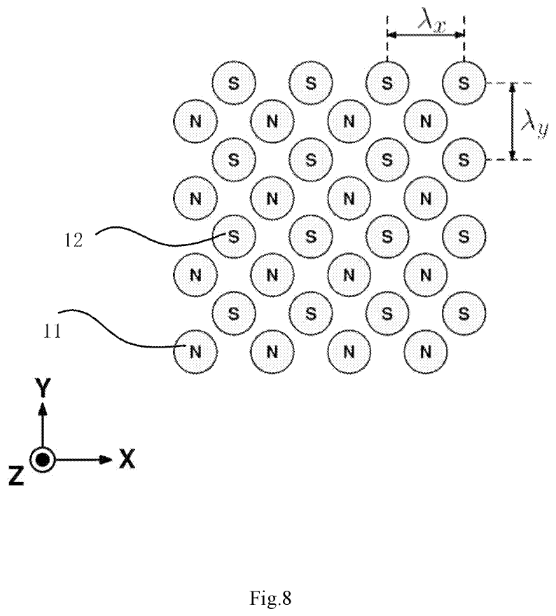

FIGS. 6-8 are schematic view showing variants of the stator magnet array according to Embodiments 1-3 of the present disclosure, in which no H magnet is used, thereby being low in cost. The arrangement of the N and S magnets in the magnet array shown in FIG. 6 is substantially the same as that of the N and S magnets in the magnet array shown in FIG. 1. The difference is that the magnet array in FIG. 6 does not include an H magnet (i.e., a third magnet). The arrangements of the magnet arrays in FIGS. 7 and 8 are substantially the same as that of the magnet array in FIG. 6, except that the N and S magnets in FIG. 7 are of a rectangle shape other than a diamond shape, and the N and S magnets in FIG. 8 are of a circular shape other than a diamond shape.

Further, the shape of the magnets in FIGS. 6-8 is not limited to rhombus, circle, square, or other shapes such as triangle, hexagram, or the like.

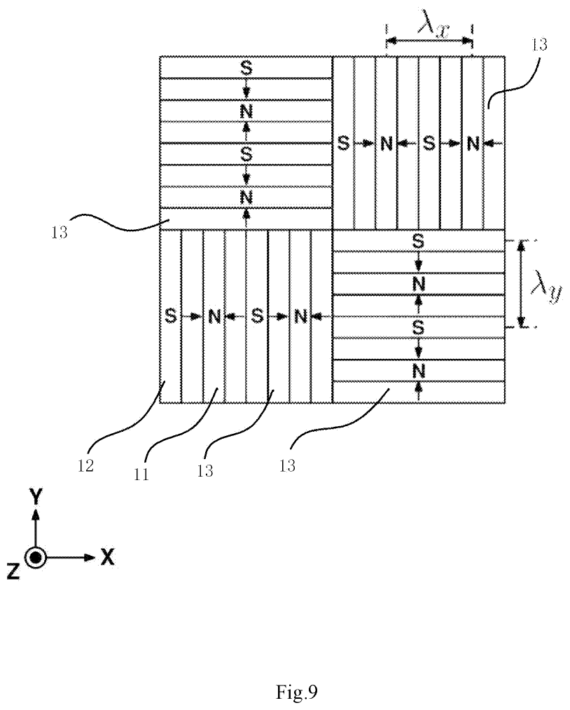

FIG. 9 is a schematic view showing another variant of the stator magnet array according to Embodiments 1-3 of the present disclosure, which also belonging to Halbuch array. With the magnet arrangement shown in FIG. 9, a plurality of coil array according to the present disclosure may be used in combination in the X-Y plane. The magnet array shown in FIG. 9 is composed of a plurality of first sub-magnet arrays and a plurality of second sub-magnet arrays, which alternately arranged with each other in the X-Y plane. The first sub-magnet array includes N magnets, S magnets and H magnets linearly extending in the direction X, the magnetization directions of these magnets are all perpendicular to the direction X and are periodically arranged in the direction Y in a Halbuch manner, in which a spatial period (the distance between two adjacent homo-polar magnets) is identified herein as λ_{y}. The second sub-magnet array includes N magnets, S magnets and H magnets linearly extending in the direction Y, the magnetization directions of these magnets are all perpendicular to the direction Y and are periodically arranged in the direction X in a Halbuch manner, in which a spatial period (the distance between two adjacent homo-polar magnets) is identified herein as ax.

The above description is only for the specific embodiments of the disclosure, but the scope of the disclosure is not limited thereto, and any changes or substitutions that can be easily conceived by those skilled in the art within the technical scope of the disclosure are also within the scope of the disclosure.

1. A displacement device, comprising:
a stator magnet array comprising a plurality of first magnets and a plurality of second magnets, the first magnets and the second magnets being arranged periodically in a first plane; and
a rotor comprising at least a first X-coil array of a plurality of first X-coils and a first Y-coil array of a plurality of first Y-coils;
wherein a body portion of the first X-coil array is disposed in a first conductor layer that is substantially parallel to the first plane, and a body portion of the first Y-coil array is disposed in a second conductor layer that is substantially parallel to the first plane, the first conductor layer and the second conductor layer are disposed at a distance from each other in a direction perpendicular to the first plane;
wherein the first X-coils comprises a pair of first XX conductors extending in a first direction and a pair of first XY conductors extending in a second direction substantially perpendicular to the first direction;
the first direction and the second direction are both substantially parallel to the first plane;
the first direction and the second direction are substantially perpendicular with each other; and
at least one of the pair of the first XX conductors of the first X-coil is disposed in the second conductor layer, and the pair of the first XY conductors are both disposed in the first conductor layer.

2. The displacement device of claim 1, wherein,
the first Y-coils comprises a pair of first YX conductors extending in the first direction and a pair of first YY conductors extending in the second direction;
at least one of the pair of the first YY conductors of the first Y-coil is disposed in the first conductor layer, and the pair of the first YX conductors are disposed in the second conductor layer.

3. The displacement device of claim 2, wherein,
the rotor further comprises a second X-coil array of a plurality of second X-coils;
the second X-coils comprises a pair of second XX conductors extending in the first direction and a pair of second XY conductors extending in the second direction;
at least one of the pair of the second XX conductors of the second X-coil is disposed in the second conductor layer, and the pair of the second XY conductors are disposed in the first conductor layer;
the rotor further comprises a second Y-coil array of a plurality of second Y-coils;
the second Y-coils comprises a pair of second YX conductors extending in the first direction and a pair of second YY conductors extending in the second direction;
at least one of the pair of the second YY conductors of the second Y-coil is disposed in the first conductor layer, and the pair of the second YX conductors are disposed in the second conductor layer.

4. The displacement device of claim 3, wherein,
the first XX conductor disposed in the second conductor layer is provided between the first YX conductor and the second YX conductor which are closest to a negative direction of the second direction, and
the second XX conductor disposed in the second conductor layer is provided between the first YX conductor and the second YX conductor which are closest to a positive direction of the second direction.

5. The displacement device of claim 3, wherein,
the first YY conductor disposed in the first conductor layer is provided between the first XY conductor and the second XY conductor which are closest to a positive direction of the first direction, and
the second YY conductor disposed in the first conductor layer is provided between the first XY conductor and the second XY conductor which are closest to a negative direction of the first direction.

6. The displacement device of claim 3, wherein,
the first XX conductor disposed in the second conductor layer is provided at a side closer to a negative direction of the second direction than one of the first YX conductors or one of the second YX conductors which is closest to the negative direction of the second direction, and
the second XX conductor disposed in the second conductor layer is provided at a side closer to the positive direction of the second direction than one of the first YX conductors or one of the second YX conductors which is closest to the positive direction of the second direction.

7. The displacement device of claim 3 wherein,
the first YY conductor disposed in the first conductor layer is provided at a side closer to a positive direction of the first direction than one of the first XY conductors or one of the second XY conductors which is closest to the positive direction of the first direction, and
the second YY conductor disposed in the first conductor layer is provided at a side closer to a negative direction of the first direction than one of the first XY conductors or one of the second XY conductors which is closest to the negative direction of the first direction.

8. The displacement device of any one of claim 3, wherein,
a distance dₓₓ in the first direction between a boundary of the first X-coil array in the negative direction of the first direction and a boundary of the second X-coil array in the negative direction of the first direction satisfies:
dₓₓ=(⅓+2n/3)λₓ, wherein, n=0,1,2,3 . . . , and
a distance d_{yy} in the second direction between a boundary of the first Y-coil array in a positive direction of the second direction and a boundary of the second Y-coil array in the positive direction of the second direction satisfies:
d_{yy}=(⅓+2n/3)λ_{y}, wherein, n=0,1,2,3 . . . ,
wherein λₓ is a distance between two adjacent homo-polar magnets in the first direction, and λ_{y} is a distance between two adjacent homo-polar magnets in the second direction.

9. The displacement device of claim 3, wherein,
a distance d_{xy} in the second direction between a boundary of the first X-coil array in the positive direction of the second direction and a boundary of the second X-coil array in the positive direction of the second direction satisfies:
d_{xy}=(n+⅙)λ_{y}, wherein, n=0,1,2,3 . . . , and
a distance d_{yx} in the first direction between a boundary of the first Y-coil array in the positive direction of the first direction and a boundary of the second Y-coil array in the positive direction of the first direction satisfies:
d_{yx}=(n+⅙)λₓ, wherein, n=0,1,2,3 . . . ,
wherein λₓ is a distance between two adjacent homo-polar magnets in the first direction, and λ_{y} is a distance between two adjacent homo-polar magnets in the second direction.

10. The displacement device of claim 2 wherein,
a distance Cₙ between the pair of the first YX conductors, extending in the first direction, of the first Y-coil, satisfies:
Cₙ=(n+½)λ_{y}, wherein, n=0,1,2,3 . . . , and
a distance Cₙ between the pair of the first XY conductors, extending in the second direction, of the first X-coil, satisfies:
Cₙ=(n+½)λₓ, wherein, n=0,1,2,3 . . .

11. The displacement device of claim 4, wherein,
the first YY conductor disposed in the first conductor layer is provided between the first XY conductor and the second XY conductor which are closest to the positive direction of the first direction, and
the second YY conductor disposed in the first conductor layer is provided between the first XY conductor and the second XY conductor which are closest to the negative direction of the first direction.

12. The displacement device of claim 4, wherein,
the first YY conductor disposed in the first conductor layer is provided at a side closer to the positive direction of the first direction than one of the first XY conductors or one of the second XY conductors which is closest to the positive direction of the first direction, and
the second YY conductor disposed in the first conductor layer is provided at a side closer to the negative direction of the first direction than one of the first XY conductors or one of the second XY conductors which is closest to the negative direction of the first direction.

13. The displacement device of claim 4, wherein,
a distance in the first direction between a boundary of the first X-coil array in the negative direction of the first direction and a boundary of the second X-coil array in the negative direction of the first direction satisfies:
dₓₓ=(⅓+2n/3)λₓ, wherein, n=0,1,2,3 . . . , and
a distance d_{yy} in the second direction between a boundary of the first Y-coil array in the positive direction of the second direction and a boundary of the second Y-coil array in the positive direction of the second direction satisfies:
d_{yy}=(⅓+2n/3)λ_{y}, wherein, n=0,1,2,3 . . . ,
wherein λₓ is a distance between two adjacent homo-polar magnets in the first direction, and λ_{y} is a distance between two adjacent homo-polar magnets in the second direction.

14. The displacement device of claim 6, wherein,
a distance dₓₓ in the first direction between a boundary of the first X-coil array in the negative direction of the first direction and a boundary of the second X-coil array in the negative direction of the first direction satisfies:
dₓₓ=(⅓+2n/3)λₓ, wherein, n=0,1,2,3 . . . , and
a distance d_{yy} in the second direction between a boundary of the first Y-coil array in the positive direction of the second direction and a boundary of the second Y-coil array in the positive direction of the second direction satisfies:
d_{yy}=(⅓+2n/3)λ_{y}, wherein, n=0,1,2,3 . . . ,
wherein λₓ is a distance between two adjacent homo-polar magnets in the first direction, and λ_{y} is a distance between two adjacent homo-polar magnets in the second direction.

15. The displacement device of claim 4, wherein,
a distance d_{xy} in the second direction between a boundary of the first X-coil array in the positive direction of the second direction and a boundary of the second X-coil array in the positive direction of the second direction satisfies:
d_{xy}=(n+⅙)λ_{y}, wherein, n=0,1,2,3 . . . , and
a distance d_{yx} in the first direction between a boundary of the first Y-coil array in the positive direction of the first direction and a boundary of the second Y-coil array in the positive direction of the first direction satisfies:
d_{yx}=(n+⅙)λₓ, wherein, n=0,1,2,3 . . . ,
wherein λₓ is a distance between two adjacent homo-polar magnets in the first direction, and λ_{y} is a distance between two adjacent homo-polar magnets in the second direction.

16. The displacement device of claim 6, wherein,
a distance d_{xy} in the second direction between a boundary of the first X-coil array in the positive direction of the second direction and a boundary of the second X-coil array in the positive direction of the second direction satisfies:
d_{xy}=(n+⅙)λ_{y}, wherein, n=0,1,2,3 . . . , and
a distance d_{yx} in the first direction between a boundary of the first Y-coil array in the positive direction of the first direction and a boundary of the second Y-coil array in the positive direction of the first direction satisfies:
d_{yx}=(n+⅙)λₓ, wherein, n=0,1,2,3 . . . ,
wherein λₓ is a distance between two adjacent homo-polar magnets in the first direction, and λ_{y} is a distance between two adjacent homo-polar magnets in the second direction.

17. The displacement device of claim 3, wherein,
a distance Cₙ between the pair of the first YX conductors, extending in the first direction, of the first Y-coil, satisfies:
Cₙ=(n+½)λ_{y}, wherein, n=0,1,2,3 . . . , and
a distance Cₙ between the pair of the first XY conductors, extending in the second direction, of the first X-coil, satisfies:
Cₙ=(n+½)λₓ, wherein, n=0,1,2,3 . . .

18. The displacement device of claim 4, wherein,
a distance Cₙ between the pair of the first YX conductors, extending in the first direction, of the first Y-coil, satisfies:
Cₙ=(n+½)λ_{y}, wherein, n=0,1,2,3 . . . , and
a distance Cₙ between the pair of the first XY conductors, extending in the second direction, of the first X-coil, satisfies:
Cₙ=(n+½)λₓ, wherein, n=0,1,2,3 . . .

19. The displacement device of claim 3, wherein,
a distance Cₙ between the pair of the first YX conductors, extending in the first direction, of the first Y-coil, satisfies:
Cₙ=(n+½)λ_{y}, wherein, n=0,1,2,3 . . . , and
a distance Cₙ between the pair of the first XY conductors, extending in the second direction, of the first X-coil, satisfies:
Cₙ=(n+½)λₓ, wherein, n=0,1,2,3 . . . .
